(19) United States
(12) Patent Application Publication
(10) Pub. No.: US 2002/0196949 A1
(43) Pub. Date: Dec. 26, 2002

(54) Hands-free device

(76) Inventors: Klaus Rodemer, Lautertal (DE); Joerg Ohlenburger, Braunfels (DE)

Correspondence Address: IANDIORIO & TESKA, INTELLECTUAL PROPERTY LAW ATTORNEYS, 260 BEAR HILL ROAD, WALTHAM, MA, 02451-1018, US

(21) Appl. No.: 10/071,389

(22) Filed: Feb. 7, 2002

(30) Foreign Application Priority Data
Feb. 7, 2001 (DE) DE 101 05 513.7

(51) Int. Cl. H04B 1/00; H03G 3/00

(52) U.S. Cl. 381/86; 381/104; 381/107

(57) ABSTRACT

A hands-free device for an automotive vehicle is designed as a unit consisting of loudspeaker (12) and microphone (20), in which the loudspeaker (12) which can be hung with a hook (6) onto the upper edge (4) of the B-pillar trim (2) is connected via an arm (18) to the microphone (20). A guide clip (26) which is fastened to the arm encompasses the safety belt (30), so that when the belt is fasted the microphone (20) rests in the neck/chest area of the driver and thus near the driver's mouth without presenting any obstacle. The loudspeaker (12) which is positioned near the B-pillar is positioned equally close to the ear, thus creating optimum preconditions for speech distinctness or intelligibility during speaking and hearing. On the other hand, in the unfastened state of the belt, the unit is suspended in the area between B-pillar and seat back without presenting any obstacle.

The present invention relates to a hands-free device for automotive vehicles comprising a loudspeaker and a microphone held on the safety belt. German patent application 100 54 118.6 describes such a hands-free device in which the loudspeaker, which is accommodated in a housing, is fastened to the upper deflection point of the safety belt and the microphone is accommodated in a housing which is displaceable on the belt. The electrical connection between the microphone and an electronic circuit accommodated in the loudspeaker housing is established via an infrared path, and a battery accommodated in the microphone housing is charged via contacts which, when the microphone housing is slid towards the loudspeaker housing, establishes a connection with corresponding cooperating contacts.

It is the object of the present invention to provide a hands-free device in which microphone and loudspeaker are combined in one unit with which the automotive vehicle can also be retrofitted without any problems and which, while the belt is being fastened, moves loudspeaker and microphone automatically into an optimum position relative to the driver's ear and mouth without presenting an obstacle or irritating the driver in any way, and which can be operated very easily without distracting the driver's attention.

This object is achieved by the features indicated in claim 1. Developments and special designs of the invention are characterized in the subclaims.

As the microphone is connected to the loudspeaker or the housing thereof via an arm designed as a flexible printed circuit board, microphone and loudspeaker are combined in one unit that can be mounted very easily and without any efforts as a whole by just being hung into the upper edge of the B-pillar trim of the automotive vehicle with the help of a suitable hook, and is connected via cable connections for power supply from the on-board electrical system to the socket of the cigarette lighter or for signal transmission via a cable to the plug connector of the cellular phone. The flexible printed circuit board can be designed easily such that it is enlarged at its upper end and offers room for accommodating the necessary electronic circuit (amplification, etc.) which has connected thereto via conductors the microphone which is fastened to the opposite end of the small conductor section acting as a connection arm. Expediently, the connection arm has slid thereonto a shrink tube whose one end projects into the loudspeaker housing and whose other end into the microphone housing clipped onto the printed circuit board, and which protects the conductors and ensures an acceptable optical appearance.

An elongated clip which is preferably mounted in the central area of the connection arm and transversely extends relative to the arm and through which the belt is running expediently serves to guide the microphone on the safety belt. For an easy threading of the belt it is expedient to provide the clip on the back with a gap or slit through which the belt can be inserted laterally and then held between the two curved ends of the clip. Furthermore, it is expedient when the hook mounted on the loudspeaker housing is configured to be longitudinally adjustable, for instance by means of an adjusting slit or a suitable catch device, so that the unit can be positioned at a higher or lower level in response to the driver's size so as to mount both the loudspeaker and the microphone as close as possible to the ear or mouth of the belted person. When the belt is detached, it can slide without any problems through the guide clip when being rolled up, and the whole unit is then suspended next to the B-pillar without presenting any obstacle. When the belt is fastened, the unit moves automatically into the correct position of use without requiring further operations.

Expediently, the microphone has provided thereon a push-button which need only be pressed by the user upon a cellular phone call to activate the hands-free device and to accept the call. For this operation the driver need also not look for a cellular phone button, whereby he would be distracted, but he “blindly” finds the button without looking for it on the microphone directly placed on his chest.

The invention shall now be explained in more detail with reference to an embodiment illustrated in the enclosed drawings, in which:

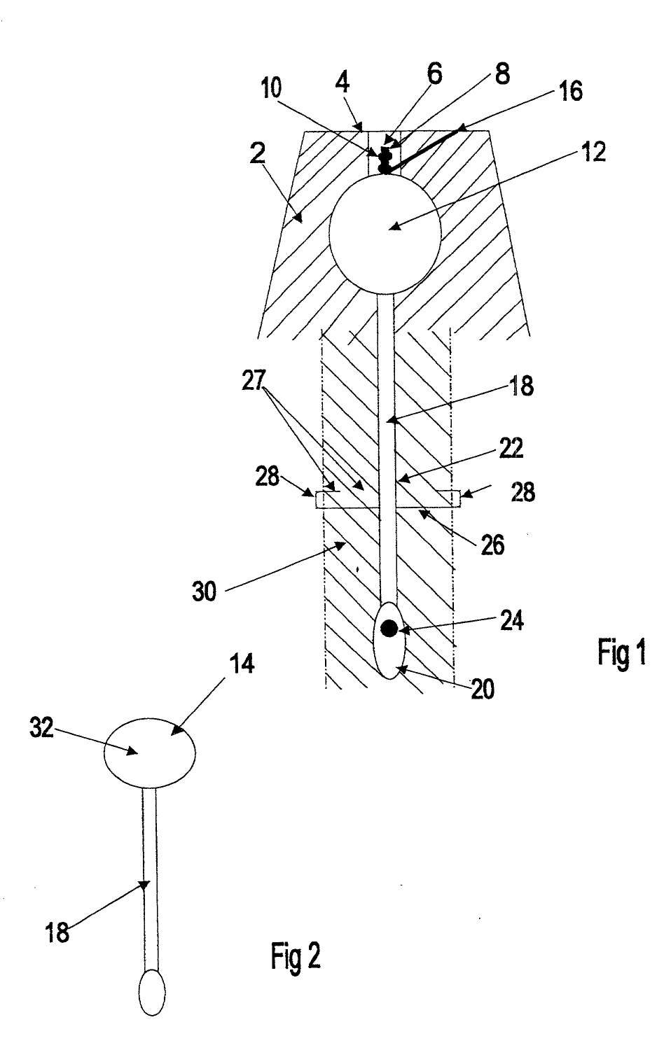

FIG. 1 is a schematic illustration of the hands-free device according to the invention; and

FIG. 2 is an illustration on a reduced scale for illustrating the printed circuit board.

FIG. 1 shows the outlined trim 2 of the B-pillar of the automotive vehicle which terminates at its upper end in a transversely extending upper edge 4. A hook 6 which may e.g. be made from a bent flat material can be hooked into said upper edge without any difficulty. The hook 6 can be displaced longitudinally with the aid of an adjusting slot 8 and catches 10 relative to the loudspeaker housing 12 or, depending on the construction, also relative to the printed circuit board 14 on which the loudspeaker housing 12 is seated with its loudspeaker (not shown) so as to adjust the unit in each case optimally relative to the head level of the respective driver.

The enlarged upper part 32 of the printed circuit board is equipped with electronic components for the circuit required for operating the device, the circuit being connected via an outlined cable connection 16 to the power supply and the cellular phone.

The printed circuit board 14 ends downwards in a small arm 18 which carries the conductors (not shown here) for connection to the microphone 20 and is protected by a pulled-up shrink tube 22 which extends upwards and downwards into the loudspeaker housing and the microphone housing, respectively. The microphone is equipped with a push-button 24 which in case of a cellular phone call is pressed for accepting the call without the need for any further operations that might distract the driver's attention. In the central area of the arm 18, there is provided a guide clip 26 which with two lateral end bows 28 grips around the belt 30, which is here only outlined in phantom line, so that the belt can freely run through the clip 26 when being rolled up or unrolled. The guide clip 26 may e.g. be bent from a round material, such as a loop or ring, but it may also be made from a flat material, so that a gap 27 is left on the rear for inserting the belt 30. In the interest of a simple assembly the housing for loudspeaker and microphone may be designed as a two-part construction with a clip attachment.

FIG. 2 separately shows the printed circuit board 14 on a reduced scale with its enlarged upper part 32 and the small arm 18. Preferably, the board is integrally made from a PCB material having a thickness of 0.5 mm, and it can thus be produced easily, reliably and at low costs. With such a small thickness, the material is very flexible so that it guarantees the insensitivity to breakage or other damage that is desired for handling the unit.

It directly follows from FIG. 1 that in the inoperative position the unit according to the invention is suspended from the belt next to the B-pillar in the space between said pillar and the seat back and does not present any obstacle at said place. When the belt is fastened, the loudspeaker moves near the ear, and the microphone rests with the belt on the chest in direct vicinity of the mouth, thereby recording the speech with a minimum amount of secondary noise, resulting in a clear speech distinctness or intelligibility without any troublesome electronic filtering. In a special embodiment of the invention, a control circuit may be provided for the reproduction volume of the loudspeaker 12, the control circuit amplifying the reproduction signals in case of loud interior noise and thus increasing the sound power output from the loudspeaker such that intelligibility remains guaranteed. At a low noise level in the car the amplification is down-regulated accordingly. To this end the interior noise can be sensed with an additional microphone placed at a suitable location, the signals of the microphone being used in a processing circuit for producing corresponding control signals for the reproduction amplifier.

1. A hands-free device for automotive vehicles comprising a loudspeaker and a microphone held on a safety belt, characterized in that said loudspeaker (12) is provided with a hook (6) to be hung onto a B-pillar trim (2) of said automotive vehicle and comprises a downwardly projecting arm (18) which carries said microphone (20) at its other end and is provided in its central area with a guide clip (26) for mounting on said belt (30).

2. The hands-free device according to claim 1, characterized in that said arm (18) is designed as a flexible printed circuit board (14) which has an enlarged upper part (32) which is equipped with the components of an electronic circuit and connected to said loudspeaker (12), and has a lower end on which said microphone (20) is fastened and connected to said electronic circuit via conductors extending over the small main part (arm 18).

3. The hands-free device according to claim 2, characterized in that said small main part (arm 18) of said printed circuit board (14) is surrounded by a shrink tube (22).

4. The hands-free device according to claim 1, characterized in that said hook (6) is longitudinally adjustable relative to said loudspeaker (12).

5. The hands-free device according to claim 4, characterized by an adjusting slot (8) and a catch device (catches 10) for fixing the longitudinal adjustment.

6. The hands-free device according to claim 1, characterized in that a push-button (24) is provided on said microphone (20).

7. The hands-free device according to claim 1, characterized in that said guide clip (26) is designed as an elongated ring (or loop) in accordance with the width of said belt with a gap (27) for inserting said belt (30).

8. The hands-free device according to claim 2, characterized in that said electronic circuit contains a volume regulating module which regulates the reproduction volume in dependence upon the interior noise of said automotive vehicle.
